(19) United States
(12) Patent Application Publication
(10) Pub. No.: US 2017/0362698 A1
(43) Pub. Date: Dec. 21, 2017

(54) VAPOR DEPOSITION MASK, VAPOR DEPOSITION DEVICE, METHOD FOR MANUFACTURING VAPOR DEPOSITION MASK, AND VAPOR DEPOSITION METHOD

(71) Applicant: Sharp Kabushiki Kaisha, Sakai City, Osaka (JP)

(72) Inventors: Yuhki KOBAYASHI, Sakai City (JP); Shinichi KAWATO, Sakai City (JP); Manabu NIBOSHI, Sakai City (JP); Kazuo TAKIZAWA, Sakai City (JP)

(21) Appl. No.: 15/532,347

(22) PCT Filed: Nov. 26, 2015
(86) PCT No.: PCT/JP2015/083157

§ 371 Date: Jun. 1, 2017

(30) Foreign Application Priority Data
Dec. 3, 2014 (JP) 2014-245348

(51) Int. Cl. C23C 16/04; C23C 16/44

(52) U.S. Cl. CPC C23C 16/04; C23C 16/44

(57) ABSTRACT

A vapor deposition mask (10) has a fine-irregularities structure (14), provided on a contact surface of the vapor deposition mask (10), which is configured to attract, by van der Waals force, a film formation target substrate (30) so as to surround a plurality of apertures (12). The contact surface makes contact with the film formation target substrate (30).

### TECHNICAL FIELD

The present invention relates to a vapor deposition mask, a vapor deposition device, a method of producing the vapor deposition mask, and a vapor deposition method.

### BACKGROUND ART

Recent years have witnessed practical use of a flat-panel display in various products and fields. This has led to a demand for a flat-panel display that is larger in size, achieves higher image quality, and consumes less power.

Under such circumstances, great attention has been drawn to an EL display device that (i) includes an EL element which uses electroluminescence (hereinafter abbreviated to “EL”) of an organic or inorganic material and that (ii) is an all-solid-state flat-panel display which is excellent in, for example, low-voltage driving, high-speed response, and light-emitting characteristics.

In order to achieve a full-color display, an EL display device includes a luminescent layer which outputs light of a desired color in correspondence with a plurality of sub-pixels constituting a pixel.

A luminescent layer is formed as a vapor deposition film on a film formation target substrate. Specifically, in a vapor deposition process, a fine metal mask (FMM) having highly-accurate apertures is used as a vapor deposition mask, and differing vapor deposition particles are vapor-deposited to each area of the film formation target substrate.

FIG. 16 is a cross-sectional view, of a film formation target substrate 530 and a vapor deposition mask 510, illustrating a common conventional vapor deposition method of forming a luminescent layer.

According to such a conventional vapor deposition method, vapor deposition particles ejected from a vapor deposition source 520 are vapor-deposited on the film formation target substrate 530 via apertures 512 of the vapor deposition mask 510 while the film formation target substrate 530 and the vapor deposition mask 510 are brought into close contact with each other (see FIG. 16). A vapor deposition film, as a luminescent layer 511 which emits a corresponding color of light, is therefore formed in each of a red sub-pixel area R, a green sub-pixel area G, and a blue sub-pixel area B in correspondence with positions of the respective apertures 512.

FIG. 17 is a cross-sectional view, of the film formation target substrate 530 and the vapor deposition mask 510, illustrating a problem of the vapor deposition method of forming a luminescent layer. Note that dotted arrows illustrated in FIG. 17 indicate a path of vapor deposition particles.

In a case where a vapor deposition is made while the film formation target substrate 530 and the vapor deposition mask 510 are away from each other (see FIG. 17), a vapor deposition pattern loses its accuracy. This consequently causes a reduction in display quality of an EL display device.

Specifically, vapor deposition particles which passed through an aperture 512 and then reached a surface of the vapor deposition mask 510 at an angle smaller than a given angle protrude to an outside of a green sub-pixel area G on which the vapor deposition particles are intended to be vapor-deposited. This causes a luminescent layer to be formed at a position displaced from an intended position of a film formation pattern, and consequently causes a so-called blur in a formed film.

Furthermore, a part of the vapor deposition particles which has protruded to the outside of the green sub-pixel area G reaches a red sub-pixel area R adjacent to the green sub-pixel area G. This causes a luminescent layer 511 that emits green light to be formed in the red sub-pixel area R, and consequently causes color mixture in the red sub-pixel area R.

Moreover, the vapor deposition particles will not reach a part of the green sub-pixel area G, and therefore no luminescent layer 511 is formed in that part of the green sub-pixel area G. This causes an amount of light emitted by the green sub-pixel area G to be uneven.

Note that, in order to prevent an amount of light emitted by a sub-pixel from becoming uneven, rotational film formation can be employed. According to the rotational film formation, a vapor deposition is made while the film formation target substrate 530 and the vapor deposition mask 510 are being rotated about a rotation axis in a direction perpendicular to their respective surfaces. However, in a case where a vapor deposition is made while the film formation target substrate 530 and the vapor deposition mask 510 as illustrated in FIG. 17 are rotated by 180°, vapor deposition particles go beyond the green sub-pixel area G, on which the vapor deposition particles are intended to be vapor-deposited, and reach the blue sub-pixel area B. This causes color mixture in the blue sub-pixel area B.

As has been discussed, according to the conventional vapor deposition method, the film formation target substrate 530 and the vapor deposition mask 510 are away from each other while a vapor deposition is made. This causes a vapor deposition pattern to lose its accuracy. Consequently, display quality of the EL display device is reduced in a case where a luminescent layer of an EL display device is formed by using the conventional vapor deposition method.

In order to address the above problem, there has been known a technique of making a vapor deposition while a film formation target substrate and a vapor deposition mask are in close contact with each other by magnetic force. According to the above method, (i) a magnetic mask is employed, and (ii) a magnet is provided on a side opposite to a side, of the film formation target substrate, on which the vapor deposition mask is provided.

With the above conventional technique, however, the magnetic force does not sufficiently act on the vapor deposition mask. This makes it difficult to cause the film formation target substrate and the vapor deposition mask to be in complete contact with each other. Furthermore, due to factors such as (i) an increase in bending of the vapor deposition mask resulting from an increase in size of the vapor deposition mask and (ii) mixing of a foreign matter in between the film formation target substrate and the vapor deposition mask, it is difficult for the film formation target substrate and the vapor deposition mask to be in complete contact with each other by magnetic force.

### CITATION LIST

### Patent Literature

[Patent Literature 1]

Japanese Patent Application Publication Tokukai No. 2012-89837 (Publication date: May 10, 2012)

### SUMMARY OF INVENTION

### Technical Problem

Patent Literature 1 discloses a glass-substrate-holding means which holds a glass substrate while a film such as a reflection layer is being formed on the glass substrate. The glass-substrate-holding means disclosed in Patent Literature 1 can hold the glass substrate because it has an attracting section which attracts and holds the glass substrate by van der Waals force.

In a case where a vapor deposition mask to which the technique disclosed in Patent Literature 1 is applied so that the vapor deposition mask includes the glass-substrate-holding means having the attracting section is employed when a vapor deposition film is to be formed on a film formation target substrate, a vapor deposition can be made while the film formation target substrate is being attracted to the vapor deposition mask.

However, the attracting section of the glass-substrate-holding means disclosed in Patent Literature 1 makes contact merely with a circumferential part of the glass substrate. Therefore, in a case where a vapor deposition is made by using the vapor deposition mask, to which the technique disclosed in Patent Literature 1 is applied so that the vapor deposition mask includes the glass-substrate-holding means having the attracting section, the film formation target substrate and the vapor deposition mask are away from each other at a center part of the vapor deposition mask. This causes a reduction in accuracy of a vapor deposition pattern.

The present invention has been attained in view of the above problem, and an objective of the present invention is to provide (i) a vapor deposition mask which can make closer contact with a film formation target substrate so as to achieve an improvement in accuracy of a vapor deposition pattern, (ii) a vapor deposition device, (iii) a method of producing the vapor deposition mask, and (iv) a vapor deposition method.

### Solution to Problem

In order to attain the above objective, a vapor deposition mask in accordance with an aspect of the present invention is a vapor deposition mask having a plurality of apertures used to form a vapor deposition material on a film formation target substrate, the vapor deposition mask including: a fine-irregularities structure, provided on a contact surface of the vapor deposition mask, which is configured to attract, by van der Waals force, the film formation target substrate so as to surround the plurality of the apertures, the contact surface making contact with the film formation target substrate.

In order to attain the above objective, a vapor deposition device in accordance with an aspect of the present invention includes: the above vapor deposition mask; and a vapor deposition source configured to deposit the vapor deposition material on the film formation target substrate via the plurality of apertures of the vapor deposition mask.

In order to attain the above objective, a method of producing a vapor deposition mask in accordance with an aspect of the present invention is a method of producing a vapor deposition mask, the vapor deposition mask having a plurality of apertures used to form a vapor deposition material on a film formation target substrate, the vapor deposition mask including: a fine-irregularities structure, provided on a contact surface of the vapor deposition mask, which is configured to attract, by van der Waals force, the film formation target substrate so as to surround the plurality of the apertures, the contact surface making contact with the film formation target substrate, the method including the steps of: (a) forming the plurality of apertures in the vapor deposition mask; and (b) forming the fine-irregularities structure on the contact surface.

In order to attain the above objective, a vapor deposition method in accordance with an aspect of the present invention is a vapor deposition method of forming a film, having a given pattern, on a film formation target substrate, the method including the steps of: bringing the film formation target substrate into contact with the above vapor deposition mask so as to attract the film formation target substrate to the vapor deposition mask; and depositing the vapor deposition material on the film formation target substrate via the plurality of apertures of the vapor deposition mask.

### Advantageous Effects of Invention

An aspect of the present invention makes it possible to provide a vapor deposition mask which can make closer contact with a film formation target substrate so as to achieve an improvement in accuracy of a vapor deposition pattern.

### BRIEF DESCRIPTION OF DRAWINGS

(a) of FIG. 1 is a lateral view illustrating a vapor deposition mask in accordance with Embodiment 1 of the present invention. (b) of FIG. 1 is a plan view illustrating the vapor deposition mask in accordance with Embodiment 1 of the present invention.

(a) of FIG. 2 is a cross-sectional view illustrating a configuration of the vapor deposition device in accordance with Embodiment 1 of the present invention. (b) of FIG. 2 is a perspective view illustrating a configuration of a main part of the vapor deposition device in accordance with Embodiment 1 of the present invention.

FIG. 3 is a cross-sectional view, of a film formation target substrate and a vapor deposition mask, illustrating a vapor deposition method using the vapor deposition device in accordance with Embodiment 1 of the present invention.

(a) of FIG. 4 is a cross-sectional view, of a film formation target substrate and a vapor deposition mask, illustrating a vapor deposition method using a conventional vapor deposition device. (b) of FIG. 4 is a cross-sectional view, of a film formation target substrate and a vapor deposition mask, illustrating the vapor deposition method using the vapor deposition device in accordance with Embodiment 1 of the present invention.

(a) of FIG. 5 is a cross-sectional view, of a film formation target substrate and a vapor deposition mask, illustrating a state where an edge part of the vapor deposition mask is in close contact with the film formation target substrate. (b) of FIG. 5 is a cross-sectional view, of the film formation target substrate and the vapor deposition mask, illustrating a state where the vicinity of the edge part of the vapor deposition mask is in close contact with the film formation target substrate. (c) of FIG. 5 is a cross-sectional view, of the film formation target substrate and the vapor deposition mask, illustrating a state where the entire vapor deposition mask is in close contact with the film formation target substrate.

(a) through (c) of FIG. 6 are cross-sectional views illustrating how the vapor deposition mask in accordance with Embodiment 1 of the present invention is sequentially produced.

FIG. 7 is a lateral view illustrating another example of the vapor deposition device in accordance with Embodiment 1 of the present invention.

FIG. 8 is a lateral view illustrating further another example of the vapor deposition device in accordance with Embodiment 1 of the present invention.

FIG. 9 is a plan view illustrating a vapor deposition mask and a film formation target substrate in accordance with Embodiment 2 of the present invention in a state where the vapor deposition mask is caused to face the film formation target substrate.

(a) of FIG. 10 is a plan view illustrating a vapor deposition mask and a film formation target substrate in accordance with Embodiment 3 of the present invention in a state where the vapor deposition mask is caused to face the film formation target substrate. (b) of FIG. 10 is a cross-sectional view taken along a line A-A of (a) of FIG. 10.

FIG. 11 is a perspective view illustrating a configuration of a main part of a vapor deposition device in accordance with Embodiment 4 of the present invention.

FIG. 12 is a lateral view illustrating the vapor deposition mask in accordance with Embodiment 4 of the present invention.

FIG. 13 is a plan view illustrating another example of the vapor deposition mask in accordance with Embodiment 4 of the present invention. (b) of FIG. 13 is a cross-sectional view taken along a line B-B of (a) of FIG. 13.

FIG. 14 is a perspective view illustrating a configuration of a main part of a vapor deposition device in accordance with Embodiment 5 of the present invention.

FIG. 15 is a lateral view illustrating a configuration of a main part of the vapor deposition device in accordance with Embodiment 5 of the present invention.

FIG. 16 is a cross-sectional view, of a film formation target substrate and a vapor deposition mask, illustrating a conventionally-common vapor deposition method of forming a luminescent layer.

FIG. 17 is a cross-sectional view, of a film formation target substrate and a vapor deposition mask, illustrating a problem of a conventional vapor deposition method of forming a luminescent layer.

### DESCRIPTION OF EMBODIMENTS

### Embodiment 1

The following description will discuss Embodiment 1 of the present invention with reference to (a) and (b) of FIG. 1 through FIG. 8.

### Configuration of Vapor Deposition Device 1

(a) of FIG. 2 is a cross-sectional view illustrating a configuration of a vapor deposition device 1 in accordance with Embodiment 1. (b) of FIG. 2 is a perspective view illustrating a configuration of a main part of the vapor deposition device 1 in accordance with Embodiment 1.

The vapor deposition device 1 is a device for forming a vapor deposition film, made of a vapor deposition material 22, on a film formation area 31 (substrate film formation area) of a film formation target substrate 30. Note that Embodiment 1 will discuss an example case where the vapor deposition film is formed as a luminescent layer 32 of an EL display device.

The vapor deposition device 1 includes a film formation chamber 2, a vapor deposition mask 10, a vapor deposition source 20, a mask frame 15, a mask holder 41 (vapor deposition mask holding member), a rotation mechanism 45, a deposition preventing plate (not illustrated), a shutter (not illustrated), and the like.

The film formation chamber 2 houses therein the vapor deposition mask 10, the vapor deposition source 20, the mask frame 15, the mask holder 41, a rotation shaft 46 of the rotation mechanism 45, the deposition preventing plate, the shutter, and the like. The film formation chamber 2 includes a vacuum pump (not illustrated) which carries out an evacuation of the film formation chamber 2 via an exhaust port (not illustrated) provided in the film formation chamber 2, so as to be kept in a vacuum during vapor deposition.

The vapor deposition source 20 is provided, on a side opposite to a side where the film formation target substrate 30 is provided, so as to face the vapor deposition mask 10. The vapor deposition source 20 can be, for example, a container which houses therein the vapor deposition material 22. Note that the vapor deposition source 20 can alternatively be a container which directly houses therein the vapor deposition material 22 or can alternatively be configured to have a pipe of load lock system so that the vapor deposition material 22 is externally supplied.

The vapor deposition source 20 has, on its upper surface (i.e., on its surface which faces the vapor deposition mask 10), an ejection hole 21 via which the vapor deposition material 22 is ejected as vapor deposition particles.

The vapor deposition source 20 generates gaseous vapor deposition particles by heating the vapor deposition material 22 so that the vapor deposition material 22 is (i) evaporated (in a case where the vapor deposition material 22 is a liquid material) or (ii) sublimated (in a case where the vapor deposition material 22 is a solid material). The vapor deposition source 20 ejects, as gaseous vapor deposition particles, the vapor deposition material 22 thus subjected to gasification toward the vapor deposition mask 10 via the ejection hole 21.

Note that each of (a) and (b) of FIG. 2 illustrates a single vapor deposition source 20. Embodiment 1 is, however, not limited as such. Alternatively, the vapor deposition device 1 in accordance with Embodiment 1 can include two or more vapor deposition sources 20.

In a case where, for example, a luminescent layer which includes a host material and a dopant material is to be formed as a vapor deposition film, the vapor deposition device 1 can include (i) a first vapor deposition source for vapor-depositing the host material and (ii) a second vapor deposition source for vapor-depositing the dopant material. In a case where a luminescent layer, which includes a host material, a dopant material, and an assist material, is to be formed as a vapor deposition film, the vapor deposition device 1 can include (i) a first vapor deposition source for vapor-depositing the host material, (ii) a second vapor deposition source for vapor-depositing the dopant material, and (iii) a third vapor deposition source for vapor-depositing the assist material.

(a) and (b) of FIG. 2 each illustrate an example case where a cylindrical vapor deposition source 20 having a single ejection hole 21 is provided. A shape of the vapor deposition source 20 and the number of ejection holes 21 are, however, not particularly limited. The vapor deposition source 20 can alternatively have, for example, a rectangular shape. A single vapor deposition source 20 needs to have at least one ejection hole 21, and can therefore have a plurality of ejection holes 21. In a case where the vapor deposition source 20 has a plurality of ejection holes 21, the plurality of ejection holes 21 can be arranged, at equal intervals, in a one-dimensional manner (i.e., in a linear manner) or in a two-dimensional manner (i.e., in a planar (tiled) manner).

The mask frame 15, configured to support the vapor deposition mask 10, is provided at the back of the vapor deposition mask 10 (see (a) of FIG. 2).

The mask frame 15, whose center part is open, has a frame shape, and is configured to support the vapor deposition mask 10 at its edge part (at its circumferential part).

The mask frame 15 is fixed to the vapor deposition mask 10, while sufficiently laying across the vapor deposition mask 10 in a tensioned state, so that the vapor deposition mask 10 does not bend. Specifically, the mask frame 15 is fixed to the vapor deposition mask 10, for example, (i) by welding, with the use of laser, a circumferential part of the vapor deposition mask 10 to the mask frame 15 or (ii) by gluing the circumferential part of the vapor deposition mask 10 to the mask frame 15. Note, however, that the mask frame 15 is not necessarily provided. Alternatively, the vapor deposition mask 10 can be directly mounted to the mask holder 41.

The mask holder 41 includes a mask trestle 42 to which the vapor deposition mask 10 and the film formation target substrate 30 are mounted while they are being kept in close contact with each other.

There are provided, down below the mask trestle 42, a deposition preventing plate (not illustrated), a shutter (not illustrated), and the like which are configured to prevent, from adhesion of an unnecessary vapor deposition material 22, the vapor deposition mask 10, the film formation area 31 of the film formation target substrate 30, the rotation mechanism 40 provided in the film formation chamber 2, and the like.

The rotation mechanism 45 includes (i) the rotation shaft 46, (ii) a rotation driving section (not illustrated) such as a motor which rotates the rotation shaft 46, and (iii) a rotation drive control section (not illustrated) configured to control an operation of the rotation driving section (see (a) of FIG. 2).

The rotation shaft 46 is coupled to the mask holder 41. The rotation drive control section controls the rotation driving section, such as a motor, to rotate the rotation shaft 46 as indicated by an arrow in (a) and (b) of FIG. 2. The rotation drive control section thus controls the mask holder 41 to rotate. The vapor deposition mask 10 and the film formation target substrate 30, each of which is held by the mask holder 41, rotate in response to the rotation of the mask holder 41.

An effect of shadows caused by the vapor deposition mask 10 can be reduced, by thus rotating the vapor deposition mask 10 and the film formation target substrate 30 with use of the rotation mechanism 45 as discussed above. This makes it possible to evenly form a film, made of the vapor deposition material, on the film formation area 31 of the film formation target substrate 30.

Embodiment 1 illustrates an example case where (i) the vapor deposition device 1 is a rotational vapor deposition device and (ii) the vapor deposition device 1 includes the rotation mechanism 45 so as not to be affected by the shadows. The vapor deposition device 1 does, however, not necessarily include the rotation mechanism 45, provided that the shadows are negligible.

Embodiment 1 illustrates an example case where (i) the mask holder 41 includes the mask trestle 42 and (ii) the vapor deposition mask 10 and the film formation target substrate 30 are mounted to the mask trestle 42. Embodiment 1 is, however, not limited as such. Alternatively, Embodiment 1 can be configured so that (i) a substrate holding member, such as an electrostatic chuck, can be employed as the mask holder 41, (ii) the film formation target substrate 30 is held by the electrostatic chuck, and (iii) the film formation target substrate 30 and the vapor deposition mask 10 are brought into close contact with each other by a lifting mechanism (not illustrated) on which the vapor deposition mask 10 is placed. It is possible to restrain bending of the film formation target substrate 30, by holding the film formation target substrate 30 with the use of the electrostatic chuck.

### Vapor Deposition Mask 10

(a) of FIG. 1 is a lateral view illustrating the vapor deposition mask 10 in accordance with Embodiment 1 of the present invention. (b) of FIG. 1 is a plan view illustrating the vapor deposition mask 10 in accordance with Embodiment 1 of the present invention.

The vapor deposition mask 10 is prepared for forming, on the film formation target substrate 30, a vapor deposition film made of the vapor deposition material 22.

The vapor deposition mask 10 has a plurality of mask aperture areas 11, which face respective film formation areas 31 of the film formation target substrate 30 when the vapor deposition mask 10 is placed to face the film formation target substrate 30 (see (b) of FIG. 1). Each of the plurality of mask aperture areas 11 has a plurality of through-holes, serving as respective apertures 12, which are arranged in a matrix manner so that vapor deposition particles (vapor deposition material 22) pass therethrough during vapor deposition.

Examples of the vapor deposition mask 10 can include a resin mask, a metal mask, and a mask having a structure in which a resin layer (e.g., resin mask) and a metal layer (e.g., metal mask) are laminated.

Examples of a metal employed as a material of which the vapor deposition mask 10 is made include magnetic metals such as iron, nickel, invar (alloy of iron and nickel), and stainless steel SUS430. Out of such magnetic metals, invar, which is an alloy of iron and nickel, can be suitably employed because it is hard to deform due to heat.

Note, however, that the metal is not limited to magnetic metal particles, and a non-magnetic metal can be alternatively employed as the metal.

Examples of a resin used as a material of which the vapor deposition mask 10 is made include polyimide, polyethylene, polyethylene naphthalate, polyethylene terephthalate, and epoxy resin. Those resins can be employed alone or in combination.

It is possible to form, by use of laser processing or the like, the apertures 12 with high accuracy, by employing the resins alone or in combination as a material of which the vapor deposition mask 10 is made. This allows an improvement in accuracy of positioning of the respective apertures 12 in a mask body 16, and consequently allows an improvement in accuracy of a pattern of a vapor deposition film.

According to the example illustrated in (b) of FIG. 2, (i) the film formation target substrate 30 has four film formation areas 31 each having a slot shape and (ii) the vapor deposition mask 10 has four mask aperture areas 11 in conformity with the four film formation areas 31. The film formation areas 31 and the mask aperture areas 11 are each not particularly limited in shape and number as above. For example, (i) the film formation areas 31 can each have a slit shape and/or (ii) the film formation target substrate 30 can have six film formation areas 31 in conformity with corresponding ones of the mask aperture areas 11 illustrated in (b) of FIG. 1.

The vapor deposition mask 10 includes the mask body 16 having a plate shape (see (a) and (b) of FIG. 1). A fine-irregularities structure 14, which attracts, by van der Waals force, the film formation target substrate 30, is provided on a surface of the mask body 16, which surface faces the film formation target substrate 30 (i.e., a contact surface which makes contact with the film formation target substrate 30), so as to surround each of the apertures 12 of the mask body 16.

The fine-irregularities structure 14 is provided on at least a part of a contact area in which, out of all surfaces of the vapor deposition mask 10, the contact surface makes contact with the film formation target substrate 30.

According to Embodiment 1, the fine-irregularities structure 14 is provided across the contact area in which, out of all surfaces of the vapor deposition mask 10, the contact surface makes contact with the film formation target substrate 30. In other words, the fine-irregularities structure 14 is provided on an entire area (shaded part illustrated in (b) of FIG. 1), other than the apertures 12, of a front surface of the vapor deposition mask 10.

The fine-irregularities structure 14 is composed of a plurality of long and thin structural elements 13 each protruding from the front surface of the mask body 16.

The plurality of structural elements 13, which constitute the fine-irregularities structure 14, are each made of (i) a material which is identical to that of the mask body 16 or (ii) a material which is obtained by, for example, corroding the front surface of the mask body 16 so that the front surface is denatured (e.g., oxidized). The plurality of structural elements 13 and the mask body 16 are formed monolithically.

The plurality of structural elements 13 are formed so that, for example, (i) each of the plurality of structural elements 13 has a length (height measuring from the front surface of the mask body 16) of several micrometers and a diameter of several hundreds of nanometers and (ii) the plurality of structural elements 13 are provided on the front surface of the mask body 16 so as to have a density of 10¹⁰ structural elements/cm².

The plurality of structural elements 13 are therefore flexible and has a structure which can attract, by van der Waals force, the film formation target substrate 30 when they are brought into contact with the film formation target substrate 30.

### Structure of Fine-Irregularities Structure 14

The following description will discuss a preferable structure of the fine-irregularities structure 14 which causes intermolecular force, which is required to bring the vapor deposition mask 10 and the film formation target substrate 30 into close contact with each other, to act on a contact surface between the vapor deposition mask 10 and the film formation target substrate 30.

In a case where the vapor deposition mask 10 is to be brought into close contact with the film formation target substrate 30 in a state where the film formation target substrate 30 is provided on a downside of the vapor deposition mask 10 in a vertical direction, a downward force acting, in the vertical direction, on the contact surface between the vapor deposition mask 10 and the film formation target substrate 30 is expressed by 0.0098×X(N), i.e., approximately (1/102)×X(N), where (i) X(gram) indicates a mass of the film formation target substrate 30 and (ii) 1 gf (1 gram-force)=0.0098N.

A condition to be satisfied by the vapor deposition mask 10 being in close contact with the film formation target substrate 30 is expressed by the following inequality (1):

F>(1/102)×X (1)

where F(N) indicates an attraction force of the entire plurality of structural elements 13 provided on the vapor deposition mask 10 (i.e., intermolecular force acting on the film formation target substrate 30 and the vapor deposition mask 10).

Note that in a case where the vapor deposition mask 10 is to be brought into close contact with the film formation target substrate 30 in a state where the film formation target substrate 30 is provided on an upper side of the vapor deposition mask 10 in the vertical direction, a mass of the vapor deposition mask 10 is indicated by X(gram) in the above inequality (1).

By satisfying the above inequality (1), the intermolecular force acting on the film formation target substrate 30 and the vapor deposition mask 10 becomes sufficient.

Note, however, that, in a case where an excessive intermolecular force acts on the film formation target substrate 30 and the vapor deposition mask 10, it becomes difficult, after the vapor deposition film is formed, to peel off the vapor deposition mask 10 from the film formation target substrate 30. The vapor deposition mask 10 can be damaged in a case where such an excessive force acts on the vapor deposition mask 10 when the vapor deposition mask 10 is peeled off from the film formation target substrate 30.

Note that, in a case where a vapor deposition mask 10 is made of an invar alloy, an NI alloy, or the like, its tensile strength is approximately 400 N/mm², and in a case where a vapor deposition mask 10 is made of polyimide or the like, its tensile strength is approximately 50 N/mm².

In view of the fact, it is preferable that the intermolecular force, acting on the film formation target substrate 30 and the vapor deposition mask 10, is smaller than the tensile strength of the vapor deposition mask 10. This allows the vapor deposition mask 10 to be easily peeled off from the film formation target substrate 30, without damaging the vapor deposition mask 10.

That is, a condition, under which the vapor deposition mask 10 is peeled off from the film formation target substrate 30 without damaging the vapor deposition mask 10, is expressed by the following inequality (2):

F<Y×S (2)

where Y indicates the tensile strength of the vapor deposition mask 10 and S indicates an area in which the plurality of structural elements 13 make contact with the film formation target substrate 30. By satisfying the inequality (2), it is possible to easily peel off the vapor deposition mask 10 from the film formation target substrate 30, while preventing the vapor deposition mask 10 from being damaged due to stress caused by a mechanical action (lifting-up and lifting-down) which occurs when the vapor deposition mask 10 is to be peeled off from the film formation target substrate 30.

The intermolecular force F is expressed by the following expression (3):

F=F₀×S (3)

where F₀ indicates the intermolecular force acting on the plurality of structural elements 13 per unit surface area and S indicates an area in which the plurality of structural elements 13, which cause the intermolecular force, make contact with the film formation target substrate 30.

A range of the intermolecular force F₀ acting on the plurality of structural elements 13 per unit surface area and a range of the area S, in which the plurality of structural elements 13, which causes the intermolecular force, make contact with the film formation target substrate 30, are therefore expressed by the following inequality (4):

(1/102)×X<F₀×S<Y×S (4)

By determining (i) the intermolecular force F₀ acting on the plurality of structural elements 13 per unit surface area and (ii) the area S in which the plurality of structural elements 13 make contact with the film formation target substrate 30 so that the above (i) and (ii) satisfy the above inequality (4), it is possible that (a) the vapor deposition mask 10 and the film formation target substrate 30 are securely in close contact with each other and (b) the vapor deposition mask 10 is peeled off from the film formation target substrate 30 without damaging the vapor deposition mask 10.

The area S, in which the plurality of structural elements 13 make contact with the film formation target substrate 30, can alternatively be determined, based on the above inequality (4) based on the mass X of the film formation target substrate 30, the tensile strength Y of the vapor deposition mask 10, and the intermolecular force F₀ acting on the plurality of structural elements 13 per unit surface area.

### Intermolecular Force Caused by Fine-Irregularities Structure 14

The following description will discuss a case where the vapor deposition mask 10 and the film formation target substrate 30 are to be brought into contact with each other in a state where the film formation target substrate 30 is provided on the underside of the vapor deposition mask 10 in the vertical direction.

The film formation target substrate 30 has a mass of approximately 15,212 grams in a case where a substrate having, for example, a density of 2.5 g/cm³ and a G10 size (305 cm×285 cm×0.07 cm) is employed as the film formation target substrate 30. It follows that the downward force acting, in the vertical direction, on a contact area between the vapor deposition mask 10 and the film formation target substrate 30 is approximately 149 (N). As such, in order for the film formation target substrate 30 and the vapor deposition mask 10 to be in close contact with each other, it is necessary to form the fine-irregularities structure 14 so that the intermolecular force, acting on the film formation target substrate 30 and the vapor deposition mask 10, exceeds 149 (N).

In a case of employing, for example, a film formation target substrate 30 having a density of 2.5 g/cm³ and a size of 32 cm×40 cm×0.07 cm, the film formation target substrate 30 has a mass of 224 grams. In such a case, the downward force, acting on the contact area between the vapor deposition mask 10 and the film formation target substrate 30, in the vertical direction is approximately 2.2 (N). In a state where the vapor deposition mask 10 and the film formation target substrate 30 are in contact with each other and in a case where (i) the intermolecular force, per unit surface area of the plurality of structural elements 13, which acts on the contact surface between the vapor deposition mask 10 and the film formation target substrate 30, in the vertical direction is 8.3 N/cm² and (ii) the intermolecular force, per unit surface area of the plurality of structural elements 13, which acts on the contact surface between the vapor deposition mask 10 and the film formation target substrate 30, in a parallel direction is 2.3 N/cm², it is possible to realize a stress sufficient for the vapor deposition mask 10 and the film formation target substrate 30 to be in close contact with each other, provided that the fine-irregularities structure 14 is formed in at least 1 cm² in total on the vapor deposition mask 10.

The following description will discuss a case where the vapor deposition mask 10 and the film formation target substrate 30 are to be brought into contact with each other in a state where the film formation target substrate 30 is provided on the underside of the vapor deposition mask 10 in the vertical direction.

The vapor deposition mask 10 has a mass of 0.04×Z (gram), in a case where an invar alloy, employed as the vapor deposition mask 10, (i) has a density of approximately 8 g/cm³, (ii) has a contact area in which, out of all surfaces of the vapor deposition mask 10, the contact surface makes contact with the film formation target substrate is Z cm² and (iii) has a thickness of 50 μm. Accordingly, the downward force acting on the contact area between the vapor deposition mask 10 and the film formation target substrate 30 is expressed by 4×Z×10⁻⁴(N).

The intermolecular force acting on the contact surface between the vapor deposition mask 10 and the film formation target substrate 30 is 8.3×Z(N) in a case where the intermolecular force, acting on the plurality of structural elements 13, is 8.3 N/cm² per unit surface area in a state where the vapor deposition mask 10 and the film formation target substrate 30 are in close contact with each other.

That is, the intermolecular force (8.3×Z(N)) acting on the contact surface between the vapor deposition mask 10 and the film formation target substrate 30 is four or more orders of magnitude greater than that of the downward force (4×Z×10⁻⁴(N)) acting on the contact area between the vapor deposition mask 10 and the film formation target substrate 30 in the vertical direction.

Note that the intermolecular force F_{0,}, acting on the plurality of structural elements 13 per unit surface area, falls within a range from approximately 0.1 N/mm² to 20 N/mm², though it varies depending on a material, a length, and a diameter of each of the plurality of structural elements 13.

### Length of Structural Element 13

In order to reduce vapor deposition shadows so that the accuracy of a vapor deposition pattern is improved, it is preferable that the vapor deposition mask 10 is thin. In order to cause the vapor deposition mask 10 to be thin in thickness, it is preferable that a structural element 13 is short.

However, if (i) a foreign matter of greater than a structural element 13 is mixed in between the vapor deposition mask 10 and the film formation target substrate 30 or (ii) the vapor deposition mask 10 has a bending of greater than a structural element 13, then the structural element 13 does not come into contact with the film formation target substrate 30. This causes the vapor deposition mask 10 to be away from the film formation target substrate 30.

A length of the structural element 13 is therefore preferably determined in accordance with (i) the bending of the vapor deposition mask 10 due to its own weight and (ii) a size of a foreign matter which happens to be mixed in between the vapor deposition mask 10 and the film formation target substrate 30.

The vapor deposition mask 10 normally has a bending of approximately 100 μm. The foreign matter, which happens to be mixed in between the vapor deposition mask 10 and the film formation target substrate 30, normally has a size of several micrometers in a normal direction of the film formation target substrate 30.

As such, the structural element 13 preferably has a length falling within a range from, for example, several micrometers to 100 micrometers.

In order to further reduce the thickness of the vapor deposition mask 10, it is more preferable that the vapor deposition mask 10 and the film formation target substrate 30 are brought into close contact with each other in a state where the structural element 13 has a length falling within a range from several hundreds of nanometers to 50 micrometers so that a foreign matter on the order of several micrometers is removed and the bending of the vapor deposition mask 10 is reduced as much as possible.

### Thickness of Structural Element 13

In a case where (i) a structural element 13 has a small diameter and (ii) a foreign matter is mixed in between the vapor deposition mask 10 and the film formation target substrate 30, the structural element 13, which has come into contact with the foreign matter, easily deforms. This makes it possible for an intermolecular distance to be kept close between (i) a molecule constituting a structural element 13 which has not come into contact with the foreign matter and (ii) a molecule constituting the film formation target substrate 30. This ultimately allows an improvement in degree of adhesion of the vapor deposition mask 10 to the film formation target substrate 30. As such, the structural element 13 preferably has a small diameter.

Specifically, the structural element 13 preferably has a diameter of not greater than several micrometers, more preferably has a diameter of not greater than several hundreds of nanometers, and still more preferably has a diameter of not greater than several tens of nanometers.

Note, however, that it is not easy to form, on the mask body 16, a structural element 13 having a diameter of not greater than several tens of nanometers. Even though such a structural element 13, having a diameter of not greater than several tens of nanometers, can be successfully formed, it is likely that the structural element 13 is insufficient in strength. This being the case, the structural element 13 preferably has a diameter falling within a range from 50 nm to 500 nm.

### Density of Structural Elements 13

The plurality of structural elements 13 are provided on a surface of the mask body 16 which surface faces the film formation target substrate 30, so as to have a density that is determined in accordance with necessary intermolecular force. More specifically, such a density is determined in accordance with a mass of one of the vapor deposition mask 10 or the film formation target substrate 30, which one is provided, in the vapor deposition step, on the underside of the other in the vertical direction. The following description will discuss a case where a vapor deposition is made in a state where the film formation target substrate 30 is provided on the underside of the vapor deposition mask 10 in the vertical direction.

The following description will discuss a case where a G10 substrate having, for example, a size of 305 cm×285 cm×0.07 cm is employed as the film formation target substrate 30.

In a case where the G10 substrate has a density of 2.5 g/cm³, the G10 substrate has a mass of 305×285×0.07×2.5≈15 kg. It follows that the downward force of approximately 150 N acts on the contact surface between the vapor deposition mask 10 and the film formation target substrate 30.

In a case where the apertures 12 occupy a space of ½ of the surface of the mask body 16 which surface faces the film formation target substrate 30, an area in which the plurality of structural elements 13 are provided is 305×285÷2≈44,000 cm².

Therefore, in order for the vapor deposition mask 10 and the film formation target substrate 30 to be in close contact with each other, it is necessary that the intermolecular force of not lower than 150 N acts on the plurality of structural elements 13 provided in an area of 44,000 cm². That is, it is necessary that the intermolecular force of 150 N/44000 cm²≈0.003 N/cm² acts on the plurality of structural elements 13 per unit surface area.

Note that the intermolecular force caused by a single structural element 13 is 10 μN. It follows that the plurality of structural elements 13 are preferably provided so as to have a density of not lower than 0.003 N/cm²÷10 μN/structural element=340 structural elements/cm².

Note, however, that (i) even in a case where a theoretically sufficient intermolecular force can act on the plurality of structural elements 13 and (ii) in a case where the plurality of structural elements 13 are provided so as to have an extremely low density, an area of a part becomes small in which an intermolecular distance between (a) a molecule constituting a structural element 13 and (b) a molecule constituting the film formation target substrate 30 comes close to several Angstroms (Å). This makes it impossible (i) to fill a gap between the foreign matter and the vapor deposition mask 10 and (ii) for the vapor deposition mask 10 and the film formation target substrate 30 to be in close contact with each other so that the plurality of structural elements 13 wrap (cover a surface of) the foreign matter.

This consequently causes no effective intermolecular force to act, around the foreign matter, on the vapor deposition mask 10 and the film formation target substrate 30, and ultimately causes the vapor deposition mask 10 and the film formation target substrate 30 to be prevented from being in close contact with each other.

In view of the fact, the density at which the plurality of structural elements 13 are provided is preferably set in accordance with the diameter of the plurality of structural elements 13. In a case where a preferable range of the diameter of the plurality of structural elements 13 is, for example, from several tens of nanometers to several hundreds of nanometers, the plurality of structural elements 13 preferably occupy a space of (10×10⁻⁷)² cm²/structural element to (100×10⁻⁷)² cm²/structural element when viewed from above. That is, the plurality of structural elements 13 are preferably provided so as to have a density which falls within a range from 10¹⁰ structural elements/cm² to 10¹² structural elements/cm².

### Vapor Deposition Method

According to a vapor deposition method using the vapor deposition device 1, the film formation target substrate 30 is first brought into contact with the vapor deposition mask 10 so that the film formation target substrate 30 is attracted to the vapor deposition mask 10 (film formation target substrate attracting step). While the vapor deposition mask 10 and the film formation target substrate 30 are in close contact with each other, the vapor deposition material 22 is deposited on the film formation target substrate 30 via the apertures 12 of the vapor deposition mask 10 (vapor deposition material depositing step).

This makes it possible to form a vapor deposition film, having a given pattern, on the film formation area 31 of the film formation target substrate 30.

The vapor deposition method in accordance with Embodiment 1 can be employed as a method of producing an EL display device, such as an organic EL display device or an inorganic EL display device which includes a luminescent layer, in a case where, for example, the luminescent layer 32 is to be formed as a vapor deposition film on a vapor deposition surface of the film formation target substrate 30.

The vapor deposition device 1 in accordance with Embodiment 1 can be also employed as a device for producing an EL display device, such as an organic EL display device or an inorganic EL display device, which includes a luminescent layer 32.

### Close Contact Between Vapor Deposition Mask 10 and Film Formation Target Substrate 30

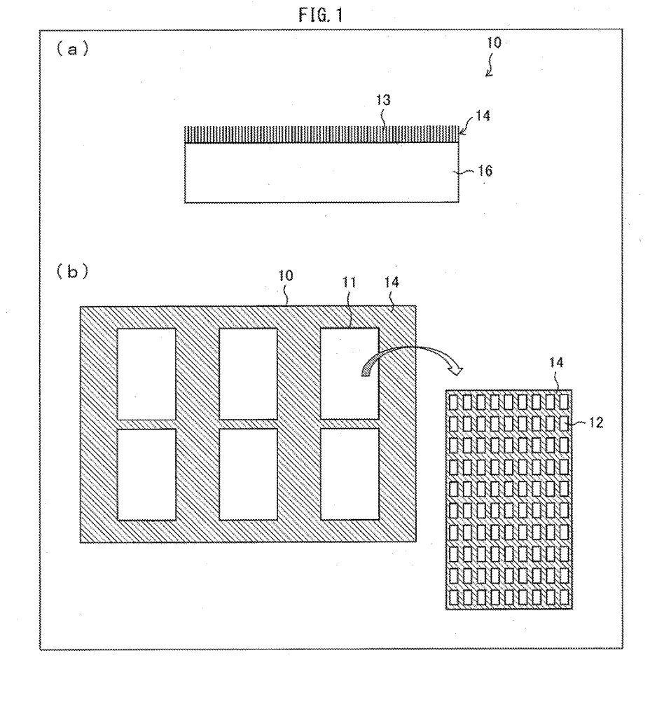

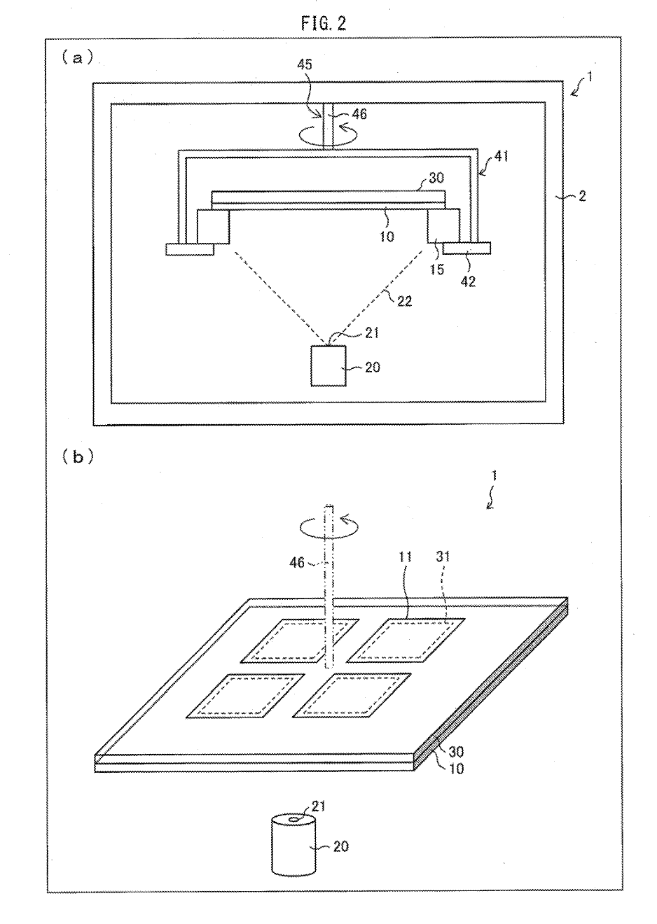

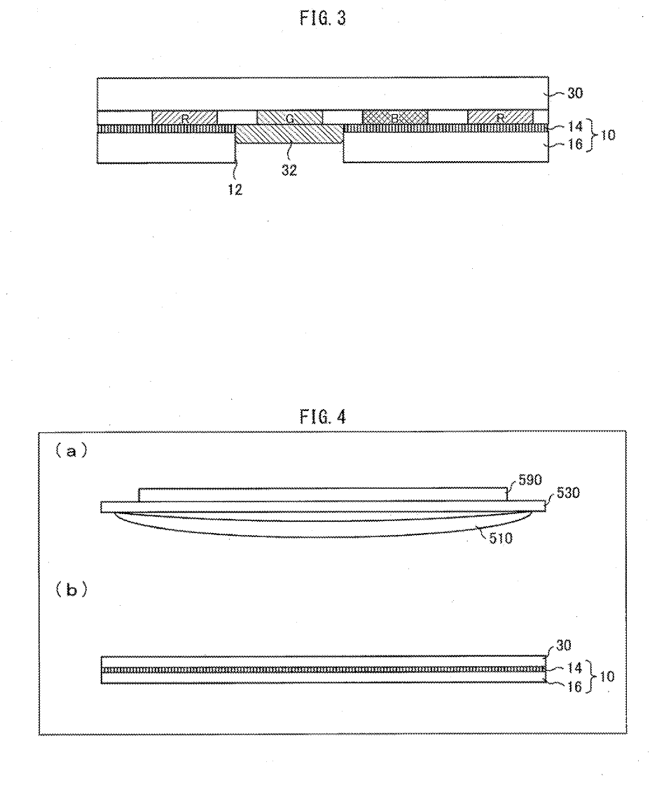

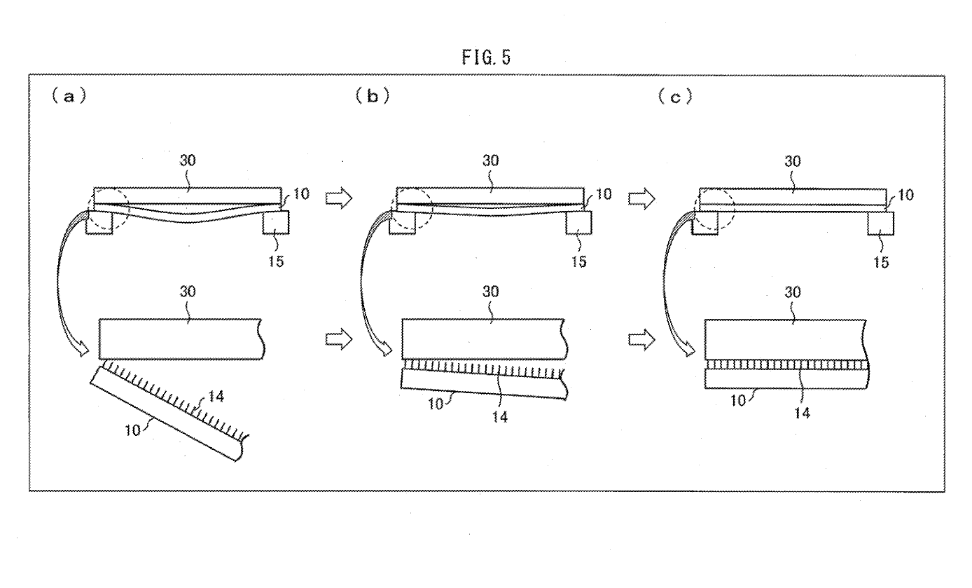

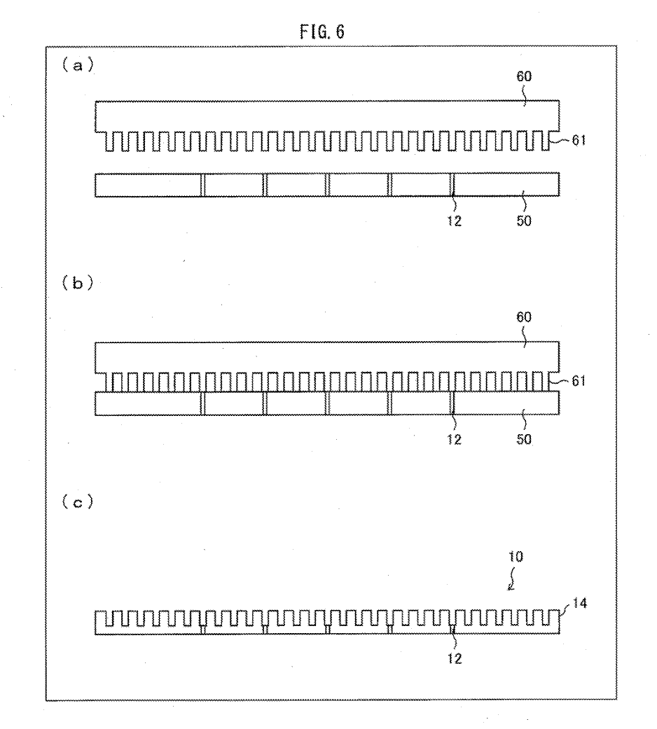

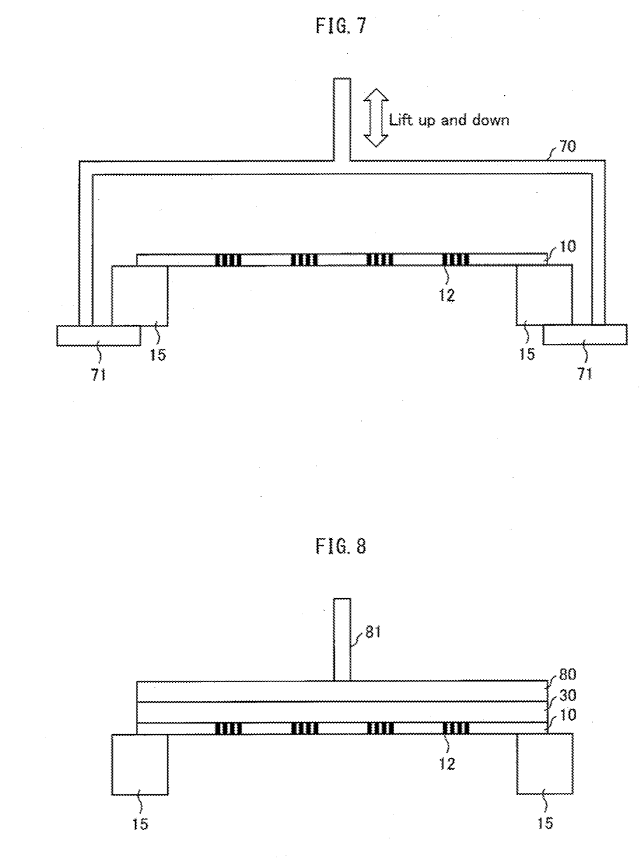

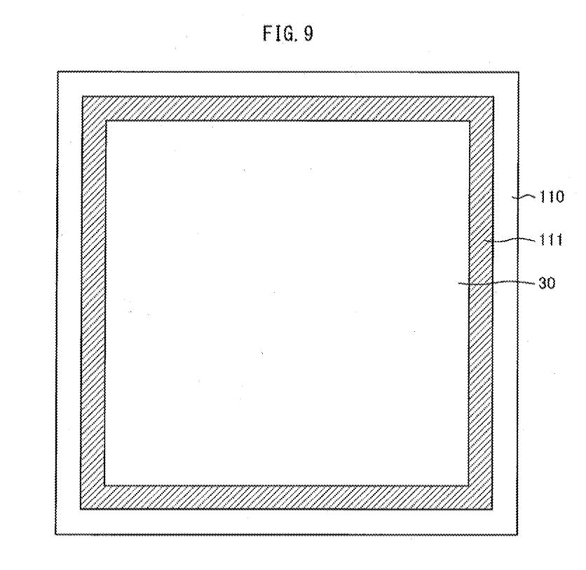

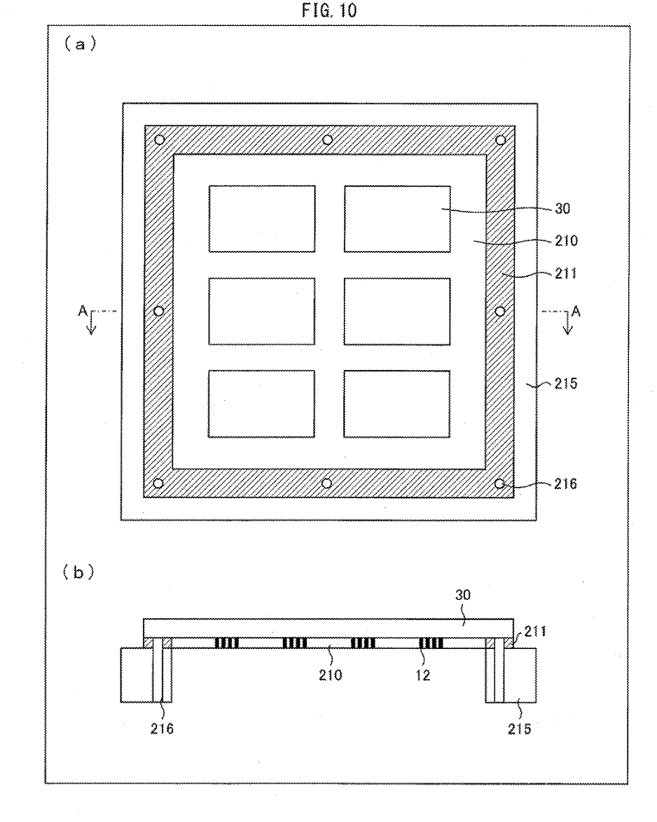

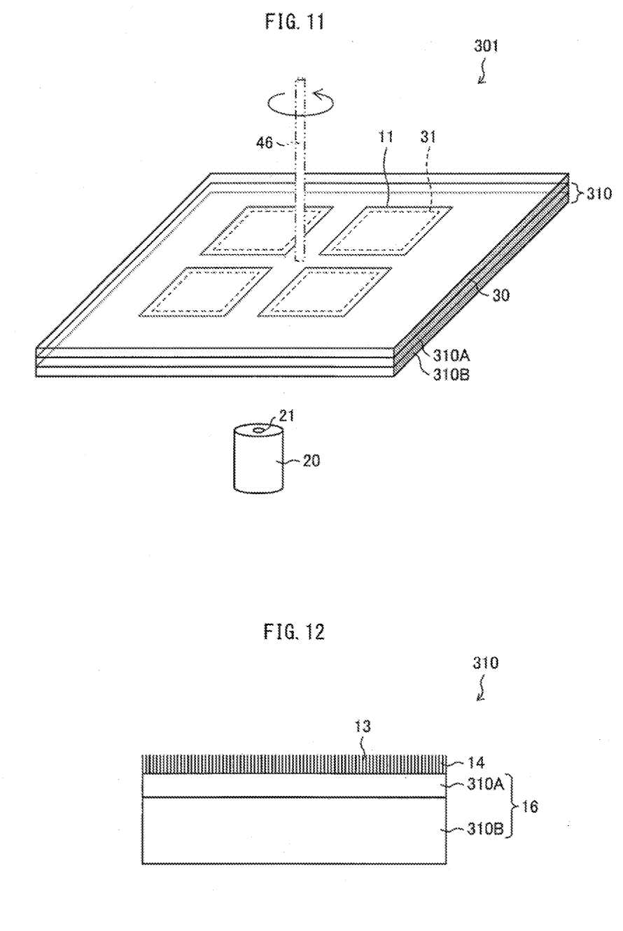

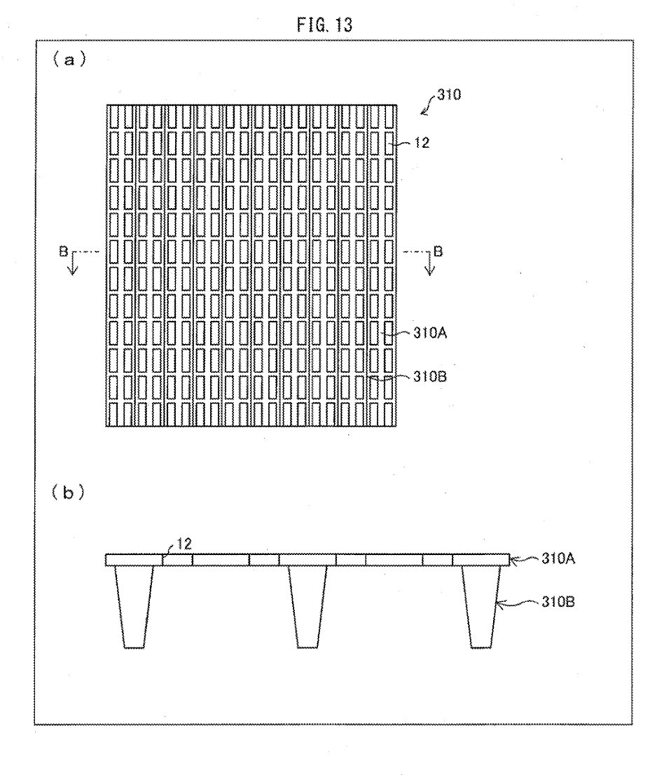

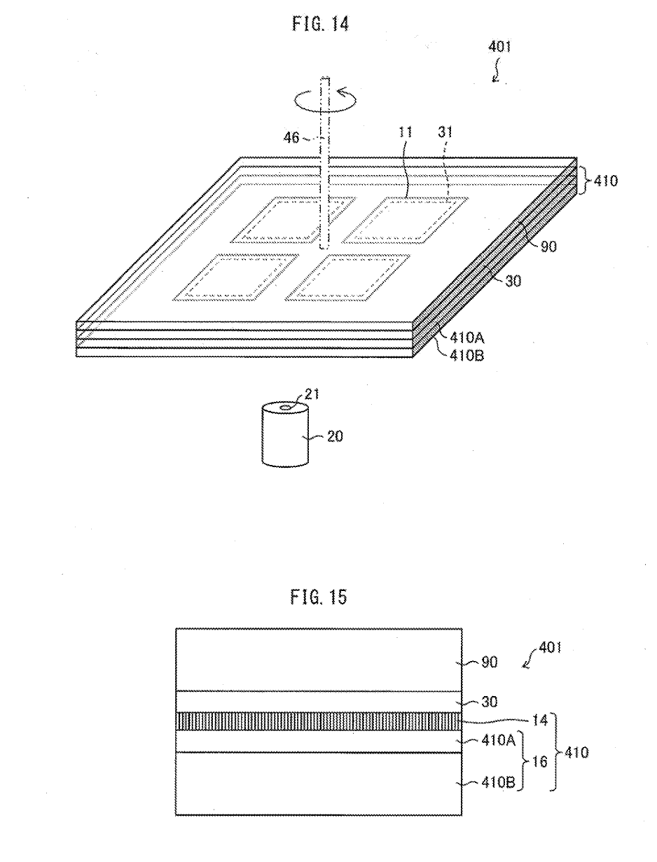

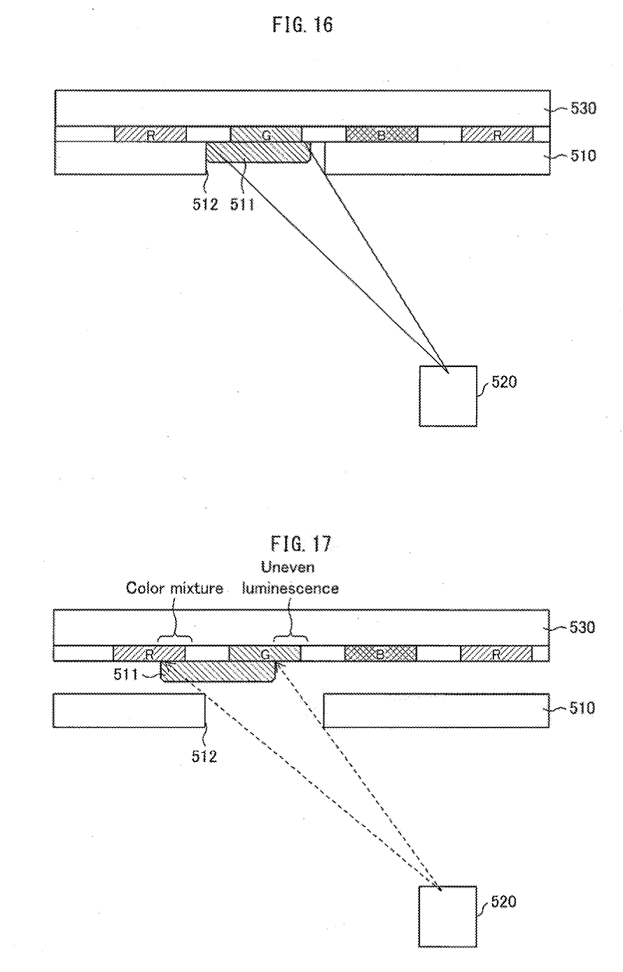

FIG. 3 is a cross-sectional view, of the film formation target substrate 30 and the vapor deposition mask 10, illustrating the vapor deposition method using the vapor deposition device 1 in accordance with Embodiment 1.

As has been discussed, the mask body 16 has, on its surface, the fine-irregularities structure 14 constituted by the plurality of structural elements 13 (see (a) of FIG. 1 and FIG. 3). With the configuration, the vapor deposition mask 10 attracts the film formation target substrate 30 because of intermolecular force (van der Waals force).

The film formation target substrate 30 has, on its surface, (i) irregularities which its base substrate inherently has and/or (ii) irregularities caused by, for example, wirings, electrodes, and driving elements provided on the film formation target substrate 30.

It follows that the vapor deposition mask 10 will not attract the film formation target substrate 30 in a case where (i) the mask body 16 does not have thereon the fine-irregularities structure 14 and (ii) the film formation target substrate 30 and the vapor deposition mask 10 are merely brought into contact with each other. Consequently, it is not possible to bring the film formation target substrate 30 and the vapor deposition mask 10 into close contact with each other.

According to Embodiment 1, however, as has been discussed, since the fine-irregularities structure 14 is provided on the contact surface, of the vapor deposition mask 10, which makes contact with the film formation target substrate 30, i.e., the contact surface, of the mask body 16, which makes contact with the film formation target substrate 30, the van der Waals force acts to allow the vapor deposition mask 10 to attract the film formation target substrate 30 so as to come into close contact with the film formation target substrate 30.

As has been discussed, the structural element 13 has a diameter, for example, on the order of a micron or less and preferably on the order of a submicron or less. The structural element 13 is therefore flexible and deformable. The structural element 13 constituting the fine-irregularities structure 14 thus has (i) a diameter smaller than the irregularities on the surface of the film formation target substrate 30 and (ii) flexibility. As such, the structural element 13 gets in between irregularities on the surface of the film formation target substrate 30 when the film formation target substrate 30 and the vapor deposition mask 10 are brought into contact with each other. This causes a significant increase in area of the part in which the intermolecular distance between (a) the molecule constituting the structural element 13 and (b) the molecule constituting the film formation target substrate 30 comes close to several Angstroms (A). This causes van der Waals force to act on the film formation target substrate 30 and the vapor deposition mask 10, and consequently causes the film formation target substrate 30 and the vapor deposition mask 10 to be brought into close contact with each other.

Since the fine-irregularities structure 14 are provided so as to surround the plurality of the apertures 12, it is possible for the vapor deposition mask 10 and the film formation target substrate 30 to securely be in close contact with each other, particularly around the apertures 12.

This makes it possible to form a vapor deposition film (luminescent layer 32) on the film formation target substrate 30 in a state where the vapor deposition mask 10 and the film formation target substrate 30 are in close contact with each other so that the vapor deposition mask 10 is prevented from being raised around the apertures 12. This consequently allows an improvement in accuracy of the vapor deposition pattern.

The fine-irregularities structure 14 is preferably formed across the contact area in which the vapor deposition mask 10 makes contact with the film formation target substrate 30. This allows the vapor deposition mask 10 and the film formation target substrate 30 to be in close contact with each other across the contact area, by van der Waals force. It is therefore possible that the vapor deposition mask 10 and the film formation target substrate 30 are sufficiently in close contact with each other across the contact area.

In a case where, for example, the vapor deposition device 1 is employed to form, as a vapor deposition film, a luminescent layer 32 of an EL display device, it is possible to prevent vapor deposition particles, which are to be formed in an intended sub-pixel area, from reaching an unintended sub-pixel area. This makes it possible to prevent a deterioration in display quality due to a blur of a formed film, color mixture, and uneven luminescence in a single pixel which are caused by a reduction in accuracy of the vapor deposition pattern.

(a) of FIG. 4 is a cross-sectional view, of a film formation target substrate 530 and a vapor deposition mask 510, illustrating a vapor deposition method using a conventional vapor deposition device. (b) of FIG. 4 is a cross-sectional view, of the film formation target substrate 30 and the vapor deposition mask 10, illustrating the vapor deposition method using the vapor deposition device 1 in accordance with Embodiment 1.

According to the conventional vapor deposition method, (i) the vapor deposition mask 510 made of a magnetic substance is employed and (ii) a magnet 590 is provided on a side opposite to a side, of the film formation target substrate 530, on which the vapor deposition mask 510 is provided. A vapor deposition is made in a state where the generated magnetic force keeps attracting the vapor deposition mask 510 toward the film formation target substrate 530.

In the above method, however, the magnetic force does not sufficiently act on the vapor deposition mask 510 and therefore the vapor deposition mask 510 bends due to its own weight. This causes the vapor deposition mask 510 and the film formation target substrate 530 to be away from each other particularly in a center part of the vapor deposition mask 510.

Furthermore, in a case where a foreign matter is mixed in between the film formation target substrate 530 and the vapor deposition mask 510, the film formation target substrate 530 and the vapor deposition mask 510 are away from each other in a part where the foreign matter is mixed. Moreover, since the vapor deposition mask 510 is highly rigid, the film formation target substrate 530 and the vapor deposition mask 510 are away from each other not only in the part where the foreign matter is mixed but also across a contact surface where the vapor deposition mask 510 makes contact with the film formation target substrate 530.

This causes a reduction in accuracy in a case where a vapor deposition pattern is formed by the conventional vapor deposition method.

In contrast, according to the vapor deposition mask 10 in accordance with Embodiment 1, the fine-irregularities structure 14 is formed on a surface, of the vapor deposition mask 10, which faces the film formation target substrate 30. This causes a significant increase in area of a part in which the intermolecular distance between (i) the molecule constituting the structural element 13 and (ii) the molecule constituting the film formation target substrate 30 comes close to several Angstroms (Å).

This causes intermolecular force to be sufficiently act on the vapor deposition mask 10 and the film formation target substrate 30, and consequently allows the vapor deposition mask 10 and the film formation target substrate 30 to be in close contact with each other.

Even in a case where a foreign matter mixed in between the vapor deposition mask 10 and the film formation target substrate 30, a structural element 13 which is in contact with the foreign matter deforms so that a intermolecular distance is kept small between (i) a molecule constituting a structural element 13 which does not come into contact with the foreign matter and (ii) the molecule constituting the film formation target substrate 30. Furthermore, since the plurality of structural elements 13 deform along a surface of the foreign matter, it is possible to fill a gap between the foreign matter and the vapor deposition mask 10.

As has been discussed above, even in a case where a foreign matter is mixed in between the vapor deposition mask 10 and the film formation target substrate 30, intermolecular force sufficiently acts on the vapor deposition mask 10 and the film formation target substrate 30. It is therefore possible to keep the vapor deposition mask 10 and the film formation target substrate 30 in close contact with each other.

This makes it possible to improve accuracy of the vapor deposition pattern.

The following description will discuss how the vapor deposition mask 10 and the film formation target substrate 30 are brought into close contact with each other.

(a) of FIG. 5 is a cross-sectional view, of the film formation target substrate 30 and the vapor deposition mask 10, illustrating a state where an edge part of the vapor deposition mask 10 is in close contact with the film formation target substrate 30. (b) of FIG. 5 is a cross-sectional view, of the film formation target substrate 30 and the vapor deposition mask 10, illustrating a state where a vicinity of the edge part of the vapor deposition mask 10 is in close contact with the film formation target substrate 30. (c) of FIG. 5 is a cross-sectional view, of the film formation target substrate 30 and the vapor deposition mask 10, illustrating a state where the entire vapor deposition mask 10 is in close contact with the film formation target substrate 30.

Bending of a conventional large vapor deposition mask increases from its edge part toward its center part due to its own weight. This causes inadequate contact between the vapor deposition mask and a film formation target substrate.

In contrast, according to the vapor deposition mask 10 in accordance with Embodiment 1, the fine-irregularities structure 14 is provided across the contact area in which the contact surface makes contact with the film formation target substrate 30. This makes it possible to cause the entire vapor deposition mask 10 to be in close contact with the film formation target substrate 30. The following description will more specifically discuss how the vapor deposition mask 10 and the film formation target substrate 30 are brought into close contact with each other.

In the step of causing the film formation target substrate 30 to attract the vapor deposition mask 10 (film formation target substrate attracting step), the vapor deposition mask 10 whose edge part is supported by the mask frame 15 is approached to the film formation target substrate 30 (see (a) of FIG. 5).

In so doing, since the vapor deposition mask 10 bends due to its own weight, a fine-irregularities structure 14, provided in a center part of the vapor deposition mask 10, does not come into contact with the film formation target substrate 30. However, since the vapor deposition mask 10 is supported by the mask frame 15, the bending of the vapor deposition mask 10 is small in its edge part. This causes the fine-irregularities structure 14, provided around the edge part of the vapor deposition mask 10, to come into contact with the film formation target substrate 30. The intermolecular force, caused by the fine-irregularities structure 14, causes the edge part of the vapor deposition mask 10 to come into close contact with the film formation target substrate 30.

Since the edge part of the vapor deposition mask 10 has come into close contact with the film formation target substrate 30, a part of the vapor deposition mask 10, which part is closer to the center part than to the edge part, is then attracted toward the film formation target substrate 30, and comes into close contact with the film formation target substrate 30 by the intermolecular force of the fine-irregularities structure 14 (see (b) of FIG. 5). A part of the vapor deposition mask 10 which part has come into close contact with the film formation target substrate 30 causes the other part of the vapor deposition mask 10 to come close to a distance where the intermolecular force occurs between the vapor deposition mask 10 and the film formation target substrate 30. This causes the vapor deposition mask 10 to come into close contact with the film formation target substrate 30 successively from the edge part to the center part.

The vapor deposition mask 10 is therefore brought into close contact with the film formation target substrate 30 so as to follow a surface shape of the film formation target substrate 30.

Consequently, the vapor deposition mask 10 comes into close contact with the film formation target substrate 30 across a surface of the vapor deposition mask 10 which surface faces the film formation target substrate 30 (see (c) of FIG. 5).

Note that the intermolecular force, acting on the vapor deposition mask 10 and the film formation target substrate 30, has an anisotropy. For example, in a state where the vapor deposition mask 10 and the film formation target substrate 30 are in close contact with each other, (i) the intermolecular force which acts in a direction perpendicular to the contact surface between the vapor deposition mask 10 and the film formation target substrate 30 is 8.3 N/cm² per unit surface area and (ii) the intermolecular force which acts in a direction parallel to the contact surface between the vapor deposition mask 10 and the film formation target substrate 30 is 2.3 N/cm² per unit surface area.

In a case where the vapor deposition mask 10 is to be peeled off from the film formation target substrate 30 after a vapor deposition film is formed on the film formation target substrate 30, it is possible for the vapor deposition mask 10 to be away from the film formation target substrate 30, by applying force in a direction, for example, at an angle of 30° with the contact surface.

### Method of Producing Vapor Deposition Mask 10

The following description will discuss a method of producing the vapor deposition mask 10 in accordance with Embodiment 1.

Each of (a) through (c) of FIG. 6 is a cross-sectional view illustrating how the vapor deposition mask 10 in accordance with Embodiment 1 is sequentially produced.

The following description will discuss the method of producing the vapor deposition mask 10 in which method a casting mold 60 (stamp) whose one side has a plurality of protrusions 61 is employed to form a fine-irregularities structure 14 on a metal plate 50 (see (a) of FIG. 6).

The metal plate 50, in which a plurality of apertures 12 have already been formed, is first caused to face the casting mold 60 whose plurality of protrusions 61 are impregnated with a liquid which can corrode or dissolve a metal (see (a) of FIG. 6).

Subsequently, the plurality of protrusions 61 of the casting mold 60 are pressed against a surface of the metal plate 50 (see (b) of FIG. 6).

This causes parts of the surface of the metal plate 50, which parts are in contact with the plurality of protrusions 61, to be corroded or dissolved. Consequently, t the plurality of protrusions 61 of the casting mold 60 are transferred to the surface of the metal plate 50 (see (c) of FIG. 6). This allows production of a vapor deposition mask 10 which has, on its surface, the fine-irregularities structure 14 constituted by a plurality of structural elements 13.

Examples of the liquid, which can corrode or dissolve metal, include acidic liquids, such as dilute hydrochloric acid and dilute sulfuric acid.

The casting mold 60 is made of a material which (i) is resistant to an acidic liquid and (ii) can be impregnated with such an acidic liquid. Examples of such a material include a crosslinkable resin and a crosslinkable rubber, and a crosslinkable polydimethylsiloxane (PDMS) elastomer is preferably employed as the material.

The plurality of protrusions 61 can be patterned all over the casting mold 60 by a conventionally-known method. Preferably, the plurality of protrusions 61 are directly patterned on the casting mold 60 by thermal nano-imprinting or UV nano-imprinting.

In the step of impregnating the casting mold 60 with an acidic liquid, the casting mold 60 can be entirely immersed in the acidic liquid. Alternatively, only the plurality of protrusions 61 can be immersed in the acidic liquid. Immersion time can be adjusted as appropriate in accordance with, for example, an immersion speed of a liquid, a size of the casting mold 60, and the like. Such immersion time is for approximately several hours.

A pressure under which the casting mold 60 is pressed against the metal plate 50 is preferably adjusted as appropriate while measuring a length of a part of the plurality of protrusions 61 which part intrudes into the metal plate 50. This makes it possible to produce a vapor deposition mask 10 having a plurality of structural elements 13 each having a given length.

The plurality of apertures 12 can be formed in the metal plate 50 by etching, laser irradiation, or the like. Note, however, that such processes can damage the plurality of structural elements 13.

In view of the damage, it is possible to restrain the damage of the plurality of structural elements 13 caused in the step (aperture forming step) of forming the apertures 12, by carrying out the step (fine-irregularities structure forming step) of forming the fine-irregularities structure 14, so that the vapor deposition mask 10 is produced, with respect to the apertures in the metal plate 50 in which the apertures are formed in advance by carrying out the step of forming the apertures in the metal plate 50.

Note that the method of producing the vapor deposition mask 10 is not limited to the above method. Alternatively, the vapor deposition mask 10 can be produced by carrying out the step of forming the plurality of apertures 12 (aperture forming step) with respect to the metal plate 50 on which the plurality of structural elements 13 have already been formed in the step of forming the fine-irregularities structure 14 with respect to the metal plate 50 (fine-irregularities structure forming step).

A vapor deposition mask 10 made of a resin can be produced by employing a resin plate instead of the metal plate 50. In a case where the vapor deposition mask 10 made of resin is to be produced, the plurality of structural elements 13 can be formed on a surface of the resin plate by carrying out thermal nano-imprinting or UV nano-imprinting with respect to the resin plate.

### Variation 1 of Vapor Deposition Device 1

FIG. 7 is a lateral view illustrating Variation 1 of the vapor deposition device 1 in accordance with Embodiment 1.

A vapor deposition device 1 in accordance with Variation 1 includes (i) a mask frame 15 which supports an edge part of a vapor deposition mask 10, (ii) a mask trestle 71 on which the mask frame 15 can be placed, and (iii) a mask-lifting mechanism 70 which can lift up and down the mask trestle 71 (see FIG. 7).

The mask frame 15, the mask trestle 71, and the mask-lifting mechanism 70 constitute a holding member which (i) holds the vapor deposition mask 10 and (ii) lifts up and down the vapor deposition mask 10.

With the above configuration, it is possible for a fine-irregularities structure 14 to be in close contact with a vapor deposition surface of a film formation target substrate 30, by lifting up the vapor deposition mask 10 toward the film formation target substrate 30 in a state where the vapor deposition mask 10 and the film formation target substrate 30 faces each other.

Note that the mask-lifting mechanism 70 is not particularly limited, provided that it can lift up and down the mask trestle 71. Alternatively, the mask-lifting mechanism 70 can be configured to (i) lift up and down a mask holder, including the mask trestle 71, with use of an actuator or (ii) lift up and down such a mask holder by winding up and down a wiring connected to the mask holder. Note that the mask holder 41 illustrated in (a) of FIG. 2 can be employed as the above mask holder. Furthermore, the mask-lifting mechanism 70 can include the rotation mechanism 45 illustrated in (a) of FIG. 2.

### Variation 2 of Vapor Deposition Device 1

FIG. 8 is a lateral view illustrating Variation 2 of the vapor deposition device 1 in accordance with Embodiment 1.

A vapor deposition device 1 in accordance with Variation 2 includes (i) a presser plate 80 which is a plate member provided on a film formation target substrate 30 attracted to a vapor deposition mask 10 and (ii) a presser-lifting mechanism 81 which can lift up and down the presser plate 80 so as to apply a load to the film formation target substrate 30 (see FIG. 8).

The presser plate 80 and the presser-lifting mechanism 81 constitute a presser member which (i) causes the vapor deposition mask 10 and the film formation target substrate 30 to be in closer contact with each other and (ii) prevents a positional displacement of the film formation target substrate 30.

This makes it possible to prevent a positional displacement of the vapor deposition mask 10 to the film formation target substrate 30 in the vapor deposition step.

Note that the presser-lifting mechanism 81 can be configured to (i) lift up and down the presser plate 80 with use of an actuator or (ii) lift up and down the presser plate 80 by winding up and down a wiring connected to the presser plate 80.

### Embodiment 2

The following description will discuss Embodiment 2 of the present invention with reference to FIG. 9. Note that, for convenience, any member of Embodiment 2 that is identical in function to a corresponding member described in Embodiment 1 is given an identical reference numeral, and descriptions of such members are omitted.

FIG. 9 is a plan view illustrating a vapor deposition mask 110 and a film formation target substrate 30 in accordance with Embodiment 2 in a state where the vapor deposition mask 110 is caused to face the film formation target substrate 30.

The vapor deposition mask 110 is identical in configuration to the vapor deposition mask 10 in accordance with Embodiment 1, except that it has, on the surface (contact surface) which faces the film formation target substrate 30, a structural element removal area 111 in which no fine-irregularities structure 14 is provided (see FIG. 9).

The structural element removal area 111 is provided around an edge part of the contact surface of the vapor deposition mask 110. More specifically, the structural element removal area 111 is provided (around a circumferential edge part) so that it surrounds an outer circumference of the film formation target substrate 30, when viewed from above, in a state where the vapor deposition mask 110 and the film formation target substrate 30 are in close contact with each other.

FIG. 9 illustrates an example where the structural element removal area 111 has a four-sided frame shape. Note, however, that the shape of the structural element removal area 111 is not limited as such. Alternatively, the structural element removal area 111 can have (i) a one-sided linear shape or (ii) a non-continuous block (banded) shape.

In a case where the intermolecular force is excessive which acts on the film formation target substrate 30 and the vapor deposition mask 110, it becomes difficult to peel off the vapor deposition mask 110 from the film formation target substrate 30 after a vapor deposition film is formed. To address such a problem, according to Embodiment 2, the structural element removal area 111 is provided in the edge part (circumferential edge part), of the vapor deposition mask 110, which is away from a group of mask aperture areas 11 of the vapor deposition mask 110. This causes a reduction in the adhesion of the film formation target substrate 30 to the vapor deposition mask 110, and consequently allows the vapor deposition mask 110 to be easily peeled off from the film formation target substrate 30.

With the configuration, mechanical force is applied, in a direction perpendicular to the contact surface, to an edge part of the vapor deposition mask 110 or the film formation target substrate 30 when the vapor deposition mask 110 is away from the film formation target substrate 30. This allows force to be applied, in an oblique direction, to the structural elements 13 via the structural element removal area 111. This makes it possible to easily separate the vapor deposition mask 110 from the film formation target substrate 30.

It is preferable that force is applied to an area where no structural element 13 is provided, when the vapor deposition mask 110 is to be away from the film formation target substrate 30. This makes it possible for the vapor deposition mask 110 to be more easily separated from the film formation target substrate 30.

As has been discussed, according to Embodiment 2, (i) the fine-irregularities structure 14 is provided around the plurality of apertures 12, of the vapor deposition mask 110, which are involved in accuracy of the pattern of a vapor deposition film, so that the vapor deposition mask 110 is prevented from being raised around the plurality of apertures 12 and (ii) the intermolecular force is reduced in a part (edge part of the vapor deposition mask 110) which is not involved in accuracy of the pattern of the vapor deposition film. This makes it possible (i) for the vapor deposition mask 110 to be securely in close contact with the film formation target substrate 30 and (ii) for the vapor deposition mask 110 to be easily separated from the film formation target substrate 30.

As with the vapor deposition mask 10 in accordance with Embodiment 1, the fine-irregularities structure 14 is provided around the plurality of apertures 12. This makes it possible for the vapor deposition mask 110 to be securely in close contact with the film formation target substrate 30 around the plurality of apertures 12. The vapor deposition mask 110 in accordance with Embodiment 2 can therefore be prevented from being raised around the plurality of apertures 12.

It is further possible for the vapor deposition mask 110 to be easily separated from the film formation target substrate 30, by applying the force to the structural element removal area 111.

Since the structural element removal area 111 is provided in the edge part of the contact surface, which makes contact with the film formation target substrate 30, it is possible for the vapor deposition mask 110 and the film formation target substrate 30 to be securely in close contact with each other and for the vapor deposition mask 110 to be partially away from the film formation target substrate 30.

### Embodiment 3

The following description will discuss Embodiment 3 of the present invention with reference to (a) and (b) of FIG. 10. Note that, for convenience, any member of Embodiment 3 that is identical in function to a corresponding member described in Embodiments 1 and 2 is given an identical reference numeral, and descriptions of such members are omitted.

(a) of FIG. 10 is a plan view illustrating a vapor deposition mask 210 and a film formation target substrate 30 in accordance with Embodiment 3 in a state where the vapor deposition mask 210 is caused to face the film formation target substrate 30. (b) of FIG. 10 is a cross-sectional view taken along a line A-A of (a) of FIG. 10.

The vapor deposition mask 210 is identical in configuration to the vapor deposition masks 10 and 110 in accordance with respective Embodiments 1 and 2, except that (i) it has, on a contact surface where the vapor deposition mask 210 makes contact with the film formation target substrate 30, a structural element removal area 211 in which the fine-irregularities structure 14 is not provided and (ii) it has, in the structural element removal area 211, suction holes 216 via which vacuum-attraction is caused (see (a) of FIG. 10).

Note that the suction holes 216 of the vapor deposition mask 210 are provided so as to extend in a mask frame 215 (see (b) of FIG. 10).

This makes it possible for the film formation target substrate 30 to be attracted to the vapor deposition mask 210, via the suction holes 216, by vacuum-attraction. Since the film formation target substrate 30 is also attracted to an area in which no fine-irregularities structure 14 is provided, the film formation target substrate 30 and the vapor deposition mask 210 can be in close contact with each other.

### Embodiment 4

The following description will discuss Embodiment 4 of the present invention with reference to FIG. 11 through (a) and (b) of FIG. 13. Note that, for convenience, any member of Embodiment 4 that is identical in function to a corresponding member described in Embodiments 1 through 3 is given an identical reference numeral, and descriptions of such members are omitted.

FIG. 11 is a perspective view illustrating a configuration of a main part of a vapor deposition device 301 in accordance with Embodiment 4.

FIG. 12 is a lateral view illustrating a vapor deposition mask 310 in accordance with Embodiment 4.

The vapor deposition mask 310 included in the vapor deposition device 301 in accordance with Embodiment 4 is identical in configuration to the vapor deposition masks 10, 110, and 210 in accordance with respective Embodiments 1 through 3, except that it includes a mask body 16 having a laminated structure which includes a resin layer 310A and a metal layer 310B (see FIG. 11 and FIG. 12). The vapor deposition mask 310 and the film formation target substrate 30 are in contact with each other via the resin layer 310A of the vapor deposition mask 310. A fine-irregularities structure 14 is provided on the resin layer 310A.

A conventional metal vapor deposition mask is hard to reduce in thickness to several tens of micrometers or smaller. This makes it difficult to form apertures with high accuracy. Furthermore, a conventional resin vapor deposition mask is easy to twist and bend. This makes it difficult to form a vapor deposition film in an intended location in the vapor deposition step.

In contrast, (i) the vapor deposition mask 310 is composed of the resin layer 310A and the metal layer 310B and (ii) the metal layer 310B has a function of supporting the resin layer 310A. This makes it possible to (i) form, by using the resin layer 310A, a vapor deposition pattern with high definition and (ii) prevent, by using the metal layer 310B, the vapor deposition mask 310 from twisting and bending.

Furthermore, by causing the resin layer 310A to serve as the contact surface which makes contact with the film formation target substrate 30, it is possible to easily and accurately form, by printing or the like, the fine-irregularities structure 14 on the resin layer 310A.

(a) of FIG. 13 is a plan view illustrating another example of the vapor deposition mask 310 in accordance with Embodiment 4. (b) of FIG. 13 is a cross-sectional view taken along a line B-B of (a) of FIG. 13.

In a case where the vapor deposition mask 310 in accordance with Embodiment 4 employs the metal layer 310B merely as a member for supporting the resin layer 310A, the metal layer 310B can be formed, at given intervals, in a linear manner on a rear surface of the resin layer 310A (see (b) of FIG. 13).

### Embodiment 5

The following description will discuss Embodiment 5 of the present invention with reference to FIGS. 14 and 15. Note that, for convenience, any member of Embodiment 5 that is identical in function to a corresponding member described in Embodiments 1 through 4 is given an identical reference numeral, and descriptions of such members are omitted.

FIG. 14 is a perspective view illustrating a configuration of a main part of a vapor deposition device 401 in accordance with Embodiment 5.

FIG. 15 is a lateral view illustrating the configuration of the main part of the vapor deposition device 401 in accordance with Embodiment 5.

The vapor deposition device 401 is identical in configuration to the vapor deposition devices 1 and 301 in accordance with Embodiments 1 through 4, except that it includes a magnet plate 90 (magnetically-attracting member) which is provided, during vapor deposition, so as to face a vapor deposition mask 410 via a film formation target substrate 30 (see FIG. 14).

As with the vapor deposition mask 310 in accordance with Embodiment 4, (i) the vapor deposition mask 410 included in the vapor deposition device 401 in accordance with Embodiment 5 includes a resin layer 410A and a metal layer 410B and (ii) a fine-irregularities structure 14 is provided on the resin layer 410A (see FIGS. 14 and 15).

Since (i) the vapor deposition mask 410 includes the metal layer 410B and (ii) the magnet plate 90 is provided on a rear surface of the film formation target substrate 30, magnetic force acts on the metal layer 410B. This causes the vapor deposition mask 410 to be attracted, and consequently allows an improvement in adhesion of the vapor deposition mask 410 to the film formation target substrate 30.

Because of the fine-irregularities structure 14 provided on the resin layer 410A, the vapor deposition mask 410 and the film formation target substrate 30 can be in close contact with each other by intermolecular force. It is possible that the film formation target substrate 30 and the vapor deposition mask 410 are more securely in close contact with each other, because the film formation target substrate 30 and the vapor deposition mask 410 are thus in close contact with each other by both of (i) the intermolecular force caused by the fine-irregularities structure 14 and (ii) the magnetic force caused by the magnet plate 90.

### Main Points

A vapor deposition mask (10, 110, 210, 310, 410) in accordance with a first aspect of the present invention is a vapor deposition mask having a plurality of apertures (12) used to form a vapor deposition material (22) on a film formation target substrate (30), the vapor deposition mask including: a fine-irregularities structure (14), provided on a contact surface of the vapor deposition mask, which is configured to attract, by van der Waals force, the film formation target substrate so as to surround the plurality of the apertures, the contact surface making contact with the film formation target substrate.

With the above configuration, it is possible for the vapor deposition mask and the film formation target substrate to be in close contact with each other even in a case where the vapor deposition mask is bending or a foreign matter is adhering to the vapor deposition mask, because the film formation target substrate is attracted to the vapor deposition mask by van der Waals force caused by the fine-irregularities structure.

The fine-irregularities structure which is provided so as to surround the plurality of apertures makes it possible for the vapor deposition mask and the film formation target substrate to be in close contact with each other around the plurality of apertures.

This makes it possible to prevent a mask from being raised around the plurality of apertures, which is a most important point to prevent (i) color mixture and/or (ii) uneven luminescence in a single pixel. It is therefore possible to provide a vapor deposition mask which allows a vapor deposition pattern to be formed with high definition.

The vapor deposition mask in accordance with a second aspect of the present invention can be configured such that, in the first aspect of the present invention, the vapor deposition mask has a laminated structure which includes a metal layer (310B) and a resin layer (310A), the resin layer serving as the contact surface.

According to the above configuration, by causing the resin layer to serve as the contact surface, it is possible to easily and accurately form, by printing or the like, the fine-irregularities structure on the contact surface. Furthermore, the above configuration makes it possible to form, by using the resin layer, a vapor deposition pattern with high definition and (ii) prevent, by using the metal layer, the vapor deposition mask from twisting and bending.

The vapor deposition mask in accordance with a third aspect of the present invention can be configured such that, in the first or second aspect of the present invention, the following inequality is satisfied:

W/102<F0×S<Y×S

where W indicates a mass of the film formation target substrate, F0 indicates van der Waals force acting on the fine-irregularities structure per unit surface area, S indicates a total area of the fine-irregularities structure, and Y indicates a tensile strength of the vapor deposition mask.

According to the above configuration, by forming the fine-irregularities structure whose F₀×S satisfies the above inequality, it is possible for the vapor deposition mask and the film formation target substrate to be securely in close contact with each other and (ii) for the vapor deposition mask to be away from the film formation target substrate without causing the vapor deposition mask to be damaged due to stress, which occurs when the vapor deposition mask is to be separated from the film formation target substrate.

The vapor deposition mask in accordance with a fourth aspect of the present invention can be configured such that, in any one of the first through third aspects of the present invention, the fine-irregularities structure is provided across the contact area in which the contact surface makes contact with the film formation target substrate.

The above configuration makes it possible for the vapor deposition mask and the film formation target substrate to be in close contact with each other, by using van der Waals force, across the contact area in which the vapor deposition mask makes contact with the film formation target substrate. It is therefore possible to that the vapor deposition mask and the film formation target substrate are sufficiently in close contact with each other across the contact area.

The vapor deposition mask in accordance with a fifth aspect of the present invention can be configured such that, in any one of the first through third aspects of the present invention, an area (structural element removal area 211), where no fine-irregularities structure is provided, is secured in an edge part of the contact surface.

The above configuration makes it possible to prevent a mask from being raised around the plurality of apertures, which is a most important point to prevent (i) color mixture and/or (ii) uneven luminescence in a single pixel. Furthermore, it is possible for the vapor deposition mask to be easily separated from the film formation target substrate by applying force to an area in which no fine-irregularities structure is provided. Note that, normally, bending of the vapor deposition mask due to its own weight is large at its center part and is comparatively small at its edge part.

Since the area, in which no fine-irregularities structure is provided, is provided in the edge part of the contact surface which makes contact with the film formation target substrate, it is possible for the vapor deposition mask and the film formation target substrate to be securely in close contact with each other and for the vapor deposition mask to be partially away from the film formation target substrate.

The vapor deposition mask in accordance with a sixth aspect of the present invention can be configured to further have, in the fifth aspect of the present invention, the area has a suction hole (216) for vacuum-attraction.

The above configuration makes it possible for the vapor deposition mask and the film formation target substrate to be in close contact with each other by causing vacuum-attraction via the suction hole. This makes it possible, to a certain extent, for the vapor deposition mask and the film formation target substrate to be in close contact with each other also in an area in which no fine-irregularities structure is provided. It is therefore possible to prevent the vapor deposition mask from being comprehensively raised above the film formation target substrate.

A vapor deposition device (1, 301, 401) in accordance with a seventh aspect of the present invention can include: a vapor deposition mask in accordance with any one of the first through sixths aspect of the present invention; and a vapor deposition source (20) configured to deposit the vapor deposition material on the film formation target substrate via the plurality of apertures of the vapor deposition mask.

According to the above configuration, the vapor deposition mask is provided so that it is possible to form a vapor deposition pattern with high definition.

The vapor deposition device in accordance with an eighth aspect of the present invention can be configured to further include, in the seventh aspect of the present invention, a holding member configured to hold the vapor deposition mask, the holding member including a lifting mechanism (70) configured to lift up and down the vapor deposition mask.

According to the above configuration, the lifting mechanism which lifts up and down the vapor deposition mask makes it possible for the fine-irregularities structure to more securely follow a surface shape of the film formation target substrate.

The vapor deposition device in accordance with a ninth aspect of the present invention can be configured to further include, in the seventh or eighth aspect of the present invention, a presser member (presser plate 80, presser-lifting mechanism 81) configured to press, from above the film formation target substrate, the film formation target substrate which has been attracted to the vapor deposition mask.

The above configuration makes it possible to prevent a substrate from displacement while a film is being formed in the vapor deposition step.

The vapor deposition device in accordance with a tenth aspect of the present invention can be configured such that, in the seventh or eighth aspect of the present invention, the vapor deposition mask has a metal layer, the vapor deposition device further including: a magnetically-attracting member (magnet plate 90) provided so as to face the vapor deposition mask via the film formation target substrate which has been attracted to the vapor deposition mask, the magnetically-attracting member attracting the metal layer by magnetic force.

It is possible that the film formation target substrate and the vapor deposition mask to be more securely in close contact with each other, because the film formation target substrate and the vapor deposition mask are in contact with each other by both of (i) van der Waals force caused by the fine-irregularities structure and (ii) the magnetic force.

A method of producing a vapor deposition mask in accordance with an eleventh aspect of the present invention can be a method of producing a vapor deposition mask, the vapor deposition mask having a plurality of apertures used to form a vapor deposition material on a film formation target substrate, the vapor deposition mask including: a fine-irregularities structure, provided on a contact surface of the vapor deposition mask, which is configured to attract, by van der Waals force, the film formation target substrate so as to surround the plurality of the apertures, the contact surface making contact with the film formation target substrate, the method including the steps of: (a) forming the plurality of apertures in the vapor deposition mask; and (b) forming the fine-irregularities structure on the contact surface.

The above method makes it possible to provide a vapor deposition mask which allows a vapor deposition pattern to be formed with high definition.

The method of producing a vapor deposition mask in accordance with a twelfth aspect of the present invention can be configured such that, in the eleventh aspect of the present invention, a metal (metal plate 50) serves as the contact surface; and in the step (b), a casting mold (60), impregnated with a liquid which corrodes or dissolves the metal, is brought into contact with the contact surface so that a pattern of the casting mold is transferred to a surface of the metal.

The above method makes it possible for the fine-irregularities structure to be easily formed on the contact surface, of the vapor deposition mask, which makes contact with the film formation target substrate, in a case where the contact surface is made of metal.

A method of producing a vapor deposition mask in accordance with a thirteenth aspect of the present invention can be configured such that, in the eleventh aspect of the present invention, a resin serves as the contact surface; and in the step (b), the fine-irregularities structure is printed on the contact surface.

The above method makes it possible for the fine-irregularities structure to be easily formed on the contact surface, of the vapor deposition mask, which makes contact with the film formation target substrate, in a case where the contact surface is made of resin.

A vapor deposition method in accordance with a fourteenth aspect of the present invention can be a vapor deposition method of forming a film, having a given pattern, on a film formation target substrate, the method including the steps of: (a) bringing the film formation target substrate into contact with a vapor deposition mask in accordance with any one of the first through sixth aspects of the present invention so as to attract the film formation target substrate to the vapor deposition mask; and (b) depositing the vapor deposition material on the film formation target substrate via the plurality of apertures of the vapor deposition mask.

With the above vapor deposition method, it is possible for the vapor deposition mask and the film formation target substrate to be in close contact with each other in the step (a) even in a case where the vapor deposition mask is bending or a foreign matter is adhering to the vapor deposition mask, because the film formation target substrate is attracted to the vapor deposition mask by van der Waals force caused by the fine-irregularities structure.

The fine-irregularities structure which is provided so as to surround the plurality of apertures makes it possible for the vapor deposition mask and the film formation target substrate to be in close contact with each other around the plurality of apertures.

This makes it possible to prevent, in the step (b), a mask from being raised around the plurality of apertures, which is a most important point to prevent (i) color mixture and/or (ii) uneven luminescence in a single pixel. The above vapor deposition method therefore makes it possible to form a vapor deposition pattern with high definition.

The present invention is not limited to the embodiments, but can be altered by a skilled person in the art within the scope of the claims. An embodiment derived from a proper combination of technical means each disclosed in a different embodiment is also encompassed in the technical scope of the present invention. Further, it is possible to form a new technical feature by combining the technical means disclosed in the respective embodiments.

### INDUSTRIAL APPLICABILITY

The present invention is suitably applicable to production of, for example, (i) an organic EL element, (ii) an inorganic EL element, (iii) an organic EL display device including the organic EL element, and (iv) an inorganic EL display device including the inorganic EL element.

### REFERENCE SIGNS LIST

1, 301, 401: Vapor deposition device
10, 210, 310, 410: Vapor deposition mask
11: Mask aperture area
12: Aperture
14: Fine-irregularities structure
15, 215: Mask frame (holding member)
16: Mask body
20: Vapor deposition source
30: Film formation target substrate
50: Metal plate
60: Casting mold
70: Mask-lifting mechanism (lifting mechanism)
71: Mask trestle (holding member)
80: Presser plate (presser member)
81: Presser-lifting mechanism (presser member)
90: Magnet plate (magnetically-attracting member)
111, 211: Structural element removal area (area in which no fine-irregularities structure is provided)
216: Suction hole
310A, 410A: Resin layer
310B, 410B: Metal layer

1. A vapor deposition mask having a plurality of apertures used to form a vapor deposition material on a film formation target substrate,
said vapor deposition mask comprising:
a fine-irregularities structure, provided on a contact surface of the vapor deposition mask, which is configured to attract, by van der Waals force, the film formation target substrate so as to surround the plurality of the apertures, the contact surface making contact with the film formation target substrate.

2. The vapor deposition mask as set forth in claim 1, wherein:
the vapor deposition mask has a laminated structure which includes a metal layer and a resin layer, the resin layer serving as the contact surface.

3. The vapor deposition mask as set forth in claim 1, wherein the following inequality is satisfied:
W/102<F₀×S<Y×S
where W indicates a mass of the film formation target substrate, F₀ indicates van der Waals force acting on the fine-irregularities structure per unit surface area, S indicates a total area of the fine-irregularities structure, and Y indicates a tensile strength of the vapor deposition mask.

4. The vapor deposition mask as set forth in claim 1, wherein:
the fine-irregularities structure is provided across a contact area in which the contact surface makes contact with the film formation target substrate.

5. The vapor deposition mask as set forth in claim 1, wherein:
an area, where no fine-irregularities structure is provided, is secured in an edge part of the contact surface.

6. The vapor deposition mask as set forth in claim 5, wherein:
the area has a suction hole for vacuum-attraction.

7. A vapor deposition device, comprising:
a vapor deposition mask recited in claim 1; and
a vapor deposition source configured to deposit the vapor deposition material on the film formation target substrate via the plurality of apertures of the vapor deposition mask.

8. A vapor deposition device as set forth in claim 7, further comprising:
a holding member configured to hold the vapor deposition mask, the holding member including a lifting mechanism configured to lift up and down the vapor deposition mask.

9. A vapor deposition device as set forth in claim 7, further comprising:
a presser member configured to press, from above the film formation target substrate, the film formation target substrate which has been attracted to the vapor deposition mask.

10. The vapor deposition device as set forth in claim 7, wherein the vapor deposition mask has a metal layer,
the vapor deposition device further comprising:
a magnetically-attracting member provided so as to face the vapor deposition mask via the film formation target substrate which has been attracted to the vapor deposition mask, the magnetically-attracting member attracting the metal layer by magnetic force.

11. A method of producing a vapor deposition mask,
the vapor deposition mask having a plurality of apertures used to form a vapor deposition material on a film formation target substrate,
said vapor deposition mask comprising:
a fine-irregularities structure, provided on a contact surface of the vapor deposition mask, which is configured to attract, by van der Waals force, the film formation target substrate so as to surround the plurality of the apertures, the contact surface making contact with the film formation target substrate,
said method comprising the steps of:
(a) forming the plurality of apertures in the vapor deposition mask; and
(b) forming the fine-irregularities structure on the contact surface.

12. The method as set forth in claim 11, wherein:
a metal serves as the contact surface; and
in the step (b), a casting mold, impregnated with a liquid which corrodes or dissolves the metal, is brought into contact with the contact surface so that a pattern of the casting mold is transferred to a surface of the metal.

13. The method as set forth in claim 11, wherein:
a resin serves as the contact surface; and
in the step (b), the fine-irregularities structure is printed on the contact surface.

14. A vapor deposition method of forming a film, having a given pattern, on a film formation target substrate,
said method comprising the steps of:
bringing the film formation target substrate into contact with a vapor deposition mask recited in claim 1 so as to attract the film formation target substrate to the vapor deposition mask; and
depositing the vapor deposition material on the film formation target substrate via the plurality of apertures of the vapor deposition mask.
